(19) United States
(12) Patent Application Publication
(10) Pub. No.: US 2008/0173870 A1
(43) Pub. Date: Jul. 24, 2008

(54) THIN FILM TRANSISTOR SUBSTRATE AND METHOD OF PRODUCING THE SAME

(76) Inventors: Byeong-beom Kim, Suwon-si (KR); Chang-oh Jeong, Suwon-si (KR); Yang-ho Bae, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/929,586

(22) Filed: Oct. 30, 2007

(30) Foreign Application Priority Data
Jan. 24, 2007 (KR) 10-2007-0007494

(51) Int. Cl. H01L 29/04; H01L 21/336

(52) U.S. Cl. 257/59; 438/158; 257/E29.003; 257/E21.413

(57) ABSTRACT

A thin film transistor substrate having low resistivity and reduced contact resistance includes a gate wiring line formed on an insulating substrate, a data wiring line crossing the gate wiring line while being insulated from the gate wiring line, and a pixel electrode connected to a portion of the data wiring line and including a zinc oxide layer pattern doped with a dopant and an anti-oxidizing substance layer pattern.

### CROSS REFERENCE TO RELATED APPLICATION

This application claims priority from Korean Patent Application No. 10-2007-0007494 filed on Jan. 24, 2007 in the Korean Intellectual Property Office, the disclosure of which is incorporated herein by reference in its entirety.

### BACKGROUND OF THE INVENTION

1. Field of the Invention

The present invention relates to thin film transistor substrates and, more particularly, to a thin film transistor substrate having reduced resistivity and contact resistance, and a method of producing the same.

2. Description of the Related Art

Currently, the liquid crystal display (LCD) is one of the most extensively used flat panel displays. The liquid crystal display is provided with two substrates on which field-generating electrodes are formed, and a liquid crystal layer that is interposed between the substrates. In the liquid crystal display, voltage is applied to the electrodes to rearrange the liquid crystal molecules of the liquid crystal layer, thereby controlling the quantity of transmitted light. Of the two substrates, the thin film transistor substrate includes a plurality of pixel electrodes provided in a matrix form. On the other substrate, a common electrode covers the entire surface of the substrate.

To realize an image in the liquid crystal display, data voltages are applied through thin film transistors, which are three-terminal elements. Additionally, a plurality of wiring lines including gate lines and data lines is formed on the substrate. Signals for controlling the thin film transistors are transmitted through the gate lines, and the data voltages are transmitted through the data lines.

To reduce the production cost of the liquid crystal display it would be advantageous to use a lower-priced material, such as a doped zinc oxide-based material for the pixel electrode. However, during the process of forming the pixel electrode using the doped zinc oxide-based material, the resistivity of the pixel electrode may be undesirably increased. Furthermore, a plurality of dangling bonds may be formed in the pixel electrode made of the above-mentioned material. These bonds may contaminate the surface of the probe used during performance testing.

Accordingly, there remains a need to form the pixel electrode using a low-priced material, having low resistivity, and that avoid contamination of the probe used in the performance testing.

### SUMMARY OF THE INVENTION

According to an aspect of the present invention, a thin film transistor substrate having lower resistivity and contact resistance includes a gate wiring line formed on an insulating substrate, a data wiring line crossing the gate wiring line while being insulated from the gate wiring line, and a pixel electrode connected to a portion of the data wiring line and including a zinc oxide layer pattern doped with a dopant and an anti-oxidizing substance layer pattern.

According to another aspect of the present invention, there is provided a method of producing a thin film transistor substrate, the method including forming a gate wiring line on an insulating substrate, forming a data wiring line crossing the gate wiring line while being insulated from the gate wiring line, and forming a pixel electrode connected to a portion of the data wiring line and including a zinc oxide layer pattern doped with a dopant and an anti-oxidizing substance layer pattern.

### BRIEF DESCRIPTION OF THE DRAWINGS

The above and other features and advantages of the present invention will become more apparent by describing in detail preferred embodiments thereof with reference to the attached drawings, in which:

FIG. 1A is a layout view illustrating a thin film transistor substrate according to a first embodiment of the present invention;

FIG. 1B is a sectional view of the thin film transistor substrate taken along the line A-A′ of FIG. 1A;

FIGS. 2 to 7 are sectional views illustrating the production of the thin film transistor substrate according to the first embodiment of the present invention;

FIG. 8 is a graph illustrating resistivity of a pixel electrode as a function of flow of oxygen gas; and

FIGS. 9 and 10 are sectional views illustrating the production of a thin film transistor substrate according to a second embodiment of the present invention.

### DESCRIPTION OF THE PREFERRED EMBODIMENTS

It will be understood that when an element or layer is referred to as being “on” another element or layer, it can be directly on to the other element or layer or intervening elements or layers may be present. In contrast, when an element is referred to as being “directly on” another element or layer, there are no intervening elements or layers present.

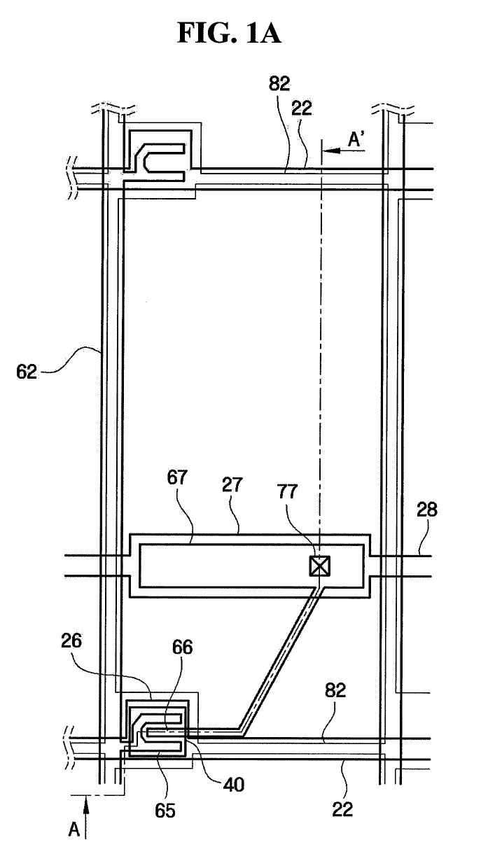

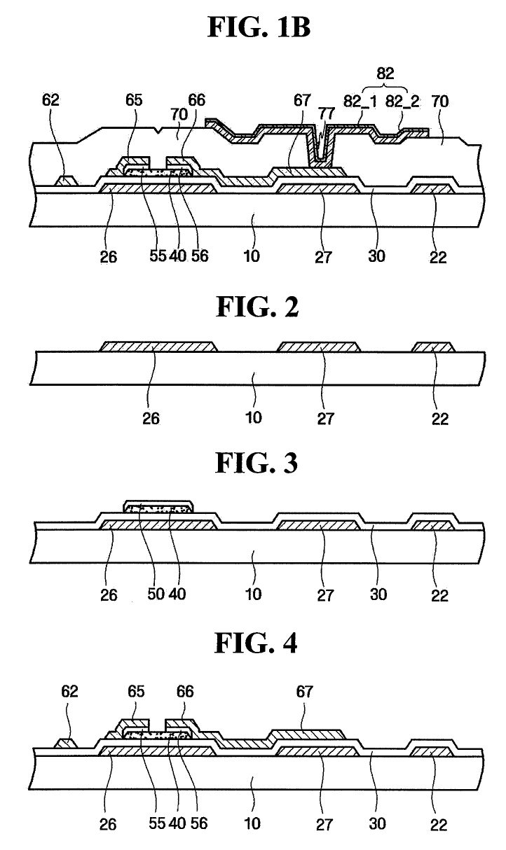

A detailed description will be given of a thin film transistor substrate according to a first embodiment of the present invention with reference to FIGS. 1A and 1B hereinafter. FIG. 1A is a layout view illustrating the thin film transistor substrate according to the first embodiment of the present invention. FIG. 1B is a sectional view of the thin film transistor substrate taken along the line A-A′ of FIG. 1A.

With reference to FIGS. 1A and 1B, a plurality of gate wiring lines 22, 26, 27, and 28 is formed on an insulating substrate 10 to transfer gate signal. The gate wiring lines 22, 26, 27, and 28 include the gate line 22 that extends in a transverse direction, the gate electrode 26 of a thin film transistor that is connected to the gate line 22 to form a protrusion Storage electrode 27 and the storage electrode line 28 are formed parallel to the gate line 22. The storage electrode line 28 extends cross a pixel region in a transverse direction. Storage electrode 27 is wider than storage electrode line 28 and overlaps the drain electrode expanded part 67 that is connected to a pixel electrode 82, as described below, to form a storage capacitor for improving the electric charge preservation ability of the pixel. The shape and the position of the above-mentioned storage electrode 27 and the storage electrode line 28 may vary, and the storage electrode 27 and the storage electrode line 28 may not be formed if the storage capacitance that is generated due to the overlapping of the pixel electrode 82 and the gate line 22 is sufficiently high.

The gate wiring lines 22, 26, 27, and 28 may be made of an aluminum-based metal, such as aluminum (Al) and an aluminum alloy, a silver-based metal, such as silver (Ag) and a silver alloy, a copper-based metal, such as copper (Cu) or a copper alloy, a molybdenum-based metal, such as molybdenum (Mo) and a molybdenum alloy, chromium (Cr), titanium (Ti), or tantalum (Ta). Additionally, the gate wiring lines 22, 26, 27, and 28 may have a multilayered structure including two conductive layers having different physical properties (not shown). Of the two conductive layers, any one conductive layer is formed of metal having low resistivity, for example, the aluminum-based metal, the silver-based metal, or the copper-based metal, so as to reduce signal delaying or a drop in voltage in the gate wiring lines 22, 26, 27, and 28. Another conductive layer may be formed of a substance having good contact properties with zinc oxide (ZnO), ITO (indium tin oxide), and IZO (indium zinc oxide), such as a molybdenum-based metal, chromium, titanium, or tantalum. With respect to the above-mentioned combination, a structure that includes a lower chromium layer and an upper aluminum layer, or a structure that includes a lower aluminum layer and an upper molybdenum layer may be formed. However, the present invention is not limited thereto. The gate wiring lines 22, 26, 27, and 28 may be made of various types of metals, and conductors.

A gate insulating layer 30 that is made of silicon nitride (SiNₓ) is formed on the insulating substrate 10 and the gate wiring lines 22, 26, 27, and 28.

An active layer pattern 40 that is made of a semiconductor such as hydrogenated amorphous silicon or polysilicon is formed to have an island shape on an upper part of the gate insulating layer 30 of the gate electrode 26. Ohmic contact layer patterns 55 and 56 that are made of a substance such as silicide or n+ hydrogenated amorphous silicon in which an n-type impurity is doped at a high concentration are formed on an upper part of the active layer pattern 40.

Data wiring lines 62, 65, 66, and 67 are formed on the ohmic contact layer patterns 55 and 56 and the gate insulating layer 30. The data wiring lines 62, 65, 66, and 67 include the data line 62 that crosses the gate line 22 in a longitudinal direction to define the pixel, the source electrode 65 that is branched from the data line 62 and extends to an upper part of the ohmic contact layer 55, the drain electrode 66 that is separated from the source electrode 65 and formed on an upper part of the ohmic contact layer 56 which is opposite to the source electrode 65 with respect to channel parts of the gate electrode 26 or the thin film transistor, and the drain electrode expanded part 67 that extends from the drain electrode 66 to overlap the storage electrode 27 and has a large area.

It is preferable that the data wiring lines 62, 65, 66, and 67 be made of refractory metal such as chromium, molybdenum-based metal, tantalum, and titanium. The data wiring lines 62, 65, 66, and 67 may have a multilayered structure that includes a lower refractory metal layer (not shown) and an upper layer (not shown) which is made of a substance having low resistance and provided on the lower refractory metal layer. Examples of the multilayered structure may include a two-layered structure of a lower chromium layer and an upper aluminum layer or a lower aluminum layer and an upper molybdenum layer, and a three-layered structure of a molybdenum layer, an aluminum layer, and a molybdenum layer.

The source electrode 65 overlaps at least a portion of the active layer pattern 40. The drain electrode 66 faces the source electrode 65 while the gate electrode 26 is provided between the drain electrode 66 and the source electrode 65, and overlaps at least a portion of the active layer pattern 40. The ohmic contact layer patterns 55 and 56 are interposed between the active layer pattern 40 and the source electrode 65 and the drain electrode 66 to reduce contact resistance.

The drain electrode expanded part 67 is provided to overlap the storage electrode 27, and forms the storage capacitor in conjunction with the storage electrode 27 while the gate insulating layer 30 is provided between the storage electrode 27 and the drain electrode expanded part 67. In the case of when the storage electrode 27 is not formed, the drain electrode expanded part 27 is not formed.

A protective layer 70 is formed on the data wiring lines 62, 65, 66, and 67 and an upper part of the active layer pattern 40 which is not covered with the data wiring lines 62, 65, 66, and 67. The protective layer 70 may be made of, for example, an organic substance having good planarization properties and photosensitivity; or a low dielectric insulating substance, such as a-Si:C:O or a-Si:O:F that is formed using plasma enhanced chemical vapor deposition (PECVD); or silicon nitride (SiNₓ) which are inorganic substances. Additionally, when the protective layer 70 is made of the organic substance, in order to prevent the organic substance of the protective layer 70 from coming into contact with an exposed portion of the active layer pattern 40 between the source electrode 65 and the drain electrode 66, an insulating layer (not shown) that is made of silicon nitride (SiNₓ) or silicon oxide (SiO₂) may be formed under the organic layer.

A contact hole 77 is formed in the protective layer 70 to expose the drain electrode expanded part 67. A pixel electrode 82 is formed on the protective layer 70 to be electrically connected through the contact hole 77 to the drain electrode 66 and to have the corresponding position to the pixel. The pixel electrode 82 to which data voltage is applied generates an electric field in conjunction with a common electrode of a color filter substrate to control alignment of the liquid crystal molecules of the liquid crystal layer between the pixel electrode 82 and the common electrode.

The pixel electrode 82 may include zinc oxide that is doped with a dopant, and an anti-oxidizing substance. In detail, the pixel electrode may include a doped zinc oxide layer pattern 82_1 that is formed of zinc oxide doped with the dopant, and an anti-oxidizing substance layer pattern 82_2 that contains an anti-oxidizing substance to prevent oxygen from being adsorbed on the doped zinc oxide layer pattern 82_1.

Even though zinc oxide is lower in price than the ITO or IZO that contains In as a main component, the resistivity of zinc oxide is about 400 to 500 μΩ·cm which is slightly higher than that of the ITO or IZO. However, zinc oxide may be doped with the dopant to reduce the resistivity of the pixel electrode 82, thereby improving the electrical properties of the pixel electrode.

The substance that is used as the dopant may be a nonmetallic element having an atomic value lower than that of an oxygen atom or a metallic element having an atomic value higher than that of zinc. A halogen element may be used as the nonmetallic element having the atomic value lower than that of an oxygen atom, and preferable examples of the nonmetallic element include F and Cl. Group Xil and XIV elements of the periodic table and the rare-earth metal may be used as the metallic element having the atomic value higher than that of zinc, and preferable examples of the metallic element may include B, Al, Ga, In, Si, Ge, Sn, Sc, Ti, Co, Cu, Y, and Hf. Zinc oxide may be doped with any one of the above-mentioned dopants or mixtures of two or more dopants.

If oxygen of zinc oxide is substituted for the nonmetallic element having the atomic value lower than that of the oxygen atom; or if zinc of zinc oxide is substituted for the metallic element having the atomic value higher than that of zinc, since the area of the vacancy through which electrons are capable of being moved is increased, the electrical properties of the pixel electrode 82 are improved. In addition, the composition ratio of zinc oxide and the dopant may be 100:1 to 100:10 in terms of weight percent. The doped zinc oxide layer pattern 82_1 that is made of the above-mentioned substance may be formed to have a thickness of, for example, 20 to 100 nm. However, the thickness of the doped zinc oxide layer pattern 82_1 is not limited thereto.

During the process of forming the doped zinc oxide layer pattern 82_1, oxygen is adsorbed on the doped zinc oxide layer pattern to reduce the area of the oxygen vacancy. Thus, the carrier concentration may be reduced to increase the resistivity of the pixel electrode 82.

In order to avoid this, the anti-oxidizing substance layer pattern 82_2 is formed on the doped zinc oxide layer pattern 82_1. The anti-oxidizing substance layer pattern 82_2 may be made of, for example, an anti-oxidizing substance containing a nitrogen atom. The anti-oxidizing substance layer pattern 82_2 may be made of nitrides of zinc oxide doped with the dopant that is selected from the group consisting of, for example, F, Cl, B, Al, Ga, In, Si, Ge, Sn, Sc, Ti, Co, Cu, Y, and Hf. The anti-oxidizing substance layer pattern 82_2 functions to prevent the doped zinc oxide layer pattern 82_1 from being oxidized and improve the electric properties of zinc oxide doped with the dopant. The anti-oxidizing substance layer pattern 82_2 that is made of the above-mentioned substance may be formed to have a thickness of, for example, 1 to 10 nm. However, the thickness of the anti-oxidizing substance layer pattern 82_2 is not limited thereto.

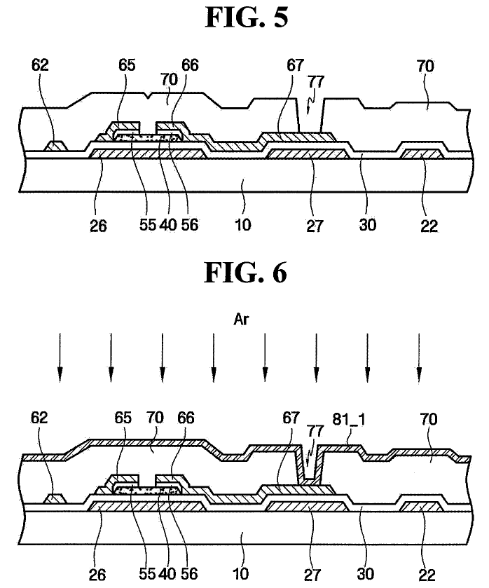

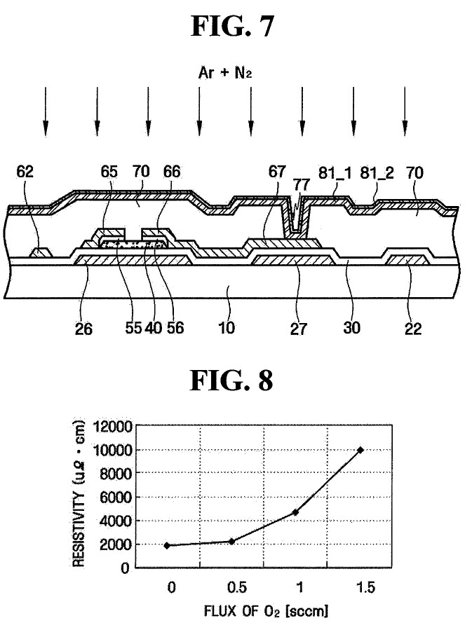

With reference to FIGS. 1A to 7, and 8, a method of producing the thin film transistor substrate according to the first embodiment of the present invention will be described in detail hereinafter. FIGS. 2 to 7 are sectional views illustrating the production of the thin film transistor substrate according to the first embodiment of the present invention. FIG. 8 is a graph illustrating resistivity of a pixel electrode as a function of flow of oxygen gas.

First, as shown in FIGS. 1A and 2, a multilayered metal layer for a gate wiring line (not shown) is layered on the insulating substrate 10, and then patterned to form the gate wiring lines 22, 26, 27, and 28 including the gate line 22, the gate electrode 26, and the storage electrode 27.

The insulating substrate 10 according to the present embodiment may be made of, for example, glass such as soda lime glass or borosilicate glass, or plastics.

A sputtering process is used to form the gate wiring lines 22, 26, 27, and 28 including the gate line 22, the gate electrode 26, and the storage electrode 27. That is, the conductive layer that is made of an aluminum-based metal, such as aluminum (Al) and an aluminum alloy, a silver-based metal, such as silver (Ag) and a silver alloy, a copper-based metal, such as copper (Cu) or a copper alloy, a molybdenum-based metal, such as molybdenum (Mo) and a molybdenum alloy, chromium (Cr), titanium (Ti), or tantalum (Ta) is deposited using, for example, the sputtering process.

Subsequently, as shown in FIG. 3, silicon nitride, an intrinsic amorphous silicon layer, and a doped amorphous silicon layer are continuously deposited on the insulating substrate 10 and the gate wiring lines 22, 26, 27, and 28 using, for example, a plasma enhanced CVD (PECVD) process to form the gate insulating layer 30 provided on the upper portion of the gate electrode 24, for example, an island type of active layer pattern 40 and the ohmic contact layer 50.

Subsequently, as shown in FIG. 4, the data wiring lines 62, 65, 66, and 67 are formed on the gate insulating layer 30 and the ohmic contact layer patterns 55 and 56 using the sputtering process. The source electrode 65 and the drain electrode 66 are separated from each other with the gate electrode 26 as the central figure, and the drain electrode expanded part 67 that extends from the drain electrode 66 overlaps the storage electrode 27.

Subsequently, the ohmic contact layer (see reference numeral 50 of FIG. 3) that is not covered with the data wiring lines 62, 65, 66, and 67 is etched to be divided with the gate electrode 26 as the central figure in order to form the ohmic contact layer patterns 55 and 56 to expose the active layer pattern 40 that is interposed between the ohmic contact layer patterns 55 and 56. In connection with this, it is preferable to perform an oxygen plasma treatment process so as to stabilize the exposed surface of the active layer pattern 40.

Subsequently, as shown in FIG. 5, a single layer or a multilayer is formed using an organic substance having excellent planarization property and photosensitivity, a low dielectric insulating substance, such as a-Si:C:O or a-Si:O:F, that is formed using plasma enhanced chemical vapor deposition (PECVD), or silicon nitride (SiNx) that is an inorganic substance to form the protective layer 70.

Subsequently, the protective layer 70 is patterned using a photolithography process to form the contact hole 77 through which the drain electrode expanded part 67 is exposed.

Subsequently, with reference to FIG. 6, the pixel electrode (see reference numeral 82 of FIG. 1B) that is connected to a portion of the data wiring lines 62, 65, 66, and 67 and formed of the zinc oxide layer pattern 81_1 and the anti-oxidizing substance layer pattern (see reference numeral 81_2 of FIG. 7) doped with the dopant is formed on the protective layer 70.

In order to form the pixel electrode, first, the zinc oxide layer 81_1 that is doped with the dopant is formed on the protective layer 70 in which the contact hole 77 is formed using a first sputtering gas. Examples of the dopant may include the nonmetallic element having the atomic value lower than that of the oxygen atom, for example, the halogen element, and preferably F or Cl. Alternatively, examples of the dopant may include the metallic element having the atomic value higher than that of zinc, for example, group XIII and XIV elements of the periodic table and the rare-earth metal, and preferably B, Al, Ga, In, Si, Ge, Sn, Sc, Ti, Co, Cu, Y, or Hf. Zinc oxide may be doped with the dopant using a known doping process to produce the zinc oxide substance doped with the dopant.

Examples of the first sputtering gas may include only argon (Ar) gas. In general, if zinc oxide that is doped with the dopant, for example, ZAO (Al doped Zn), is subjected to the sputtering process using the sputtering gas containing oxygen, the resistivity of ZAO is increased.

With reference to FIG. 8, it can be seen that if the flow of argon gas is set to 100 sccm and the flow of oxygen is increased, the resistivity of ZAO is increased. In particular, it can be seen that when the flow of oxygen is 0.5 to 1.5 sccm, the resistivity of ZAO is rapidly increased. Furthermore, the following Table 1 shows the connection between the flow of oxygen of the sputtering gas and the transmittance of the pixel electrode (see reference numeral 82 of FIG. 1A) that is formed of ZAO to light having a wavelength of 550 nm.

TABLE 1

Flow of oxygen (sccm)

| | 0 | 0.5 | 1 | 1.5 |
|---|---|---|---|---|
| Transmittance (%) | 85.64 | 85.2 | 84.45 | 83.84 |

From the above-mentioned Table 1, it can be seen that the transmittance of the pixel electrode (see reference numeral 82 of FIG. 1A) is reduced as the flow of oxygen is increased.

Accordingly, in the case of when zinc oxide doped with the dopant is subjected to the sputtering process using only argon gas which does not contain oxygen like the present embodiment, it can be seen that a pixel electrode (see reference numeral 82 of FIG. 1A) is formed having reduced resistivity and high transmittance. The flow of argon gas may be about 40 to 300 sccm, pressure in the chamber may be 0.1 to 2.0 Pa during the sputtering, and power may be 5 to 15 kW. Since the pressure in the chamber is 0.1 to 2.0 Pa is almost a vacuum during the sputtering process, the inflow of a substance that deteriorates the zinc oxide layer 81_1 doped with, for example, oxygen gas, should be prevented during the sputtering process. The sputtering process using the first sputtering gas according to the present embodiment may be, for example, a DC sputtering process.

Subsequently, with reference to FIG. 7, zinc oxide doped with the dopant is subjected to the sputtering process using the second sputtering gas on an upper side of the doped zinc oxide layer 81_1 to form an anti-oxidizing substance layer 81_2 containing zinc oxide and the anti-oxidizing substance. When the doped zinc oxide layer 81_1 is formed using only argon gas which does not contain oxygen as the first sputtering gas, oxygen may nevertheless be adsorbed onto the doped zinc oxide layer 81_1 before the subsequent processes are performed, thereby adversely affecting electrical properties of the pixel electrode. Therefore, the anti-oxidizing substance layer 81_2 is formed using the second sputtering gas which contains, for example, nitrogen gas. The second sputtering gas may be a gas mixture which contains argon and nitrogen gases. With respect to this, a flow ratio of the argon gas and the nitrogen gas may be 1:4 to 4:1 in the measured amounts of sccm units. Accordingly, the anti-oxidizing substance layer 81_2 may be made of, for example, the anti-oxidizing substance which contains a nitrogen atom. The anti-oxidizing substance layer 81_2 may be made of, for example, nitrides of zinc oxide doped with the dopant that is selected from the group consisting of F, Cl, B, Al, Ga, In, Si, Ge, Sn, Sc, Ti, Co, Cu, Y, and Hf.

Subsequently, the doped zinc oxide layer 81_1 and the anti-oxidizing substance layer 81_2 may be etched using, for example, an etching solution that contains a phosphoric acid, a nitric acid, and an acetic acid as main components to produce the pixel electrode 82 that includes the doped zinc oxide layer pattern 82_1 and the anti-oxidizing substance layer pattern 82_2 shown in FIGS. 1A and 1B.

Until now, the method of producing the thin film transistor substrate in which the active layer patterns and the data wiring lines are formed by means of the photolithography process using different masks has been described. However, the present invention can be applied to the method of producing the thin film transistor substrate in which the active layer patterns and the data wiring lines are formed by means of the photolithography process using a single photoresist pattern.

Furthermore, the pixel electrode may be formed by forming the data wiring lines, layering the photoresist patterns and the conductive substance for the pixel electrode, and performing the lift-off of the photoresist pattern and the conductive substance for the pixel electrode on the upper side of the photoresist pattern. In this case, it is not necessary to use the mask or the etching solution during the patterning of the pixel electrode.

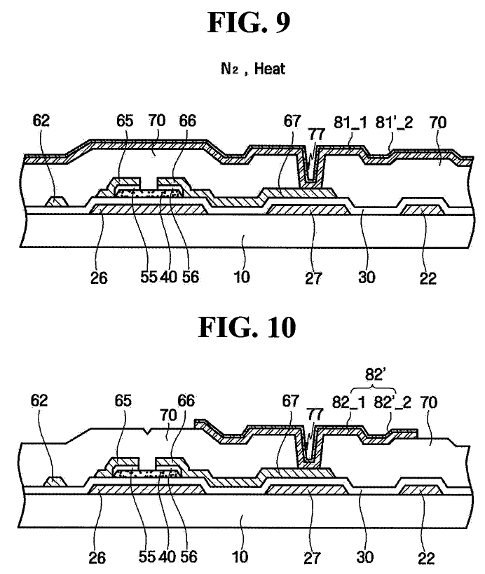

A method of producing a thin film transistor substrate according to a second embodiment of the present invention will be described with reference to FIGS. 2 to 6, 9, and 10 hereinafter. FIGS. 9 and 10 are sectional views illustrating the production of the thin film transistor substrate according to the second embodiment of the present invention.

First, the gate wiring lines 22, 26, 27, and 28, the gate insulating layer 30, the active layer pattern 40, the ohmic contact layer patterns 55 and 56, the data wiring lines 62, 65, 66, and 67, the protective layer 70, and the doped zinc oxide layer 81_1 are formed according to the procedure shown in FIGS. 2 to 6. Like the former embodiment, the doped zinc oxide layer 81_1 may be formed by performing the sputtering process in respect to zinc oxide doped with the dopant using, for example, only the argon gas as the first sputtering gas.

Subsequently, with reference to FIG. 9, the doped zinc oxide layer 81_1 is subjected to a heat treatment process in a nitrogen gas atmosphere to form an anti-oxidizing substance layer 81′_2 on an upper side of the doped zinc oxide layer 81_1. The anti-oxidizing substance layer 81′_2 according to the present embodiment may be made of the same material as the anti-oxidizing substance layer 81_2 according to the former embodiment.

If the doped zinc oxide layer 81_1 is subjected to the heat treatment process in the nitrogen gas atmosphere, the electrical properties of the doped zinc oxide layer 81_1, such as resistivity, are improved. As shown in the following Table 2, the resistivities of the doped zinc oxide layers 81_1 are compared to each other in respect to the case of when the doped zinc oxide layer 81_1 is subjected to the heat treatment process in the nitrogen gas atmosphere and the case of when the doped zinc oxide layer 81_1 is subjected to the heat treatment process in an air atmosphere.

TABLE 2

Heat treatment
atmosphere

| | Air | Nitrogen gas |
|---|---|---|
| Resistivity (μΩ · cm) | 2200 | 1627 |

As shown in the above-mentioned Table 2, if the doped zinc oxide layer 81_1 is subjected to the heat treatment process in the nitrogen gas atmosphere, the resistivity of the doped zinc oxide layer 81_1 is significantly reduced as compared to the case of when the doped zinc oxide layer 81_1 is subjected to the heat treatment process in an oxygen gas atmosphere. Accordingly, the resistivity of the pixel electrode (see reference numeral 82′ of FIG. 10) that is formed by patterning the doped zinc oxide layer 81_1 and the anti-oxidizing substance layer 81′_2 is reduced to improve the electrical properties of the thin film transistor substrate.

The temperature of the heat treatment process may be preferably about 100 to about 300° C., and more preferably about 150 to about 250° C. so as to form the nitrides of doped zinc oxide on the upper side of the doped zinc oxide layer 81_1.

Subsequently, the doped zinc oxide layer 81_1 and the anti-oxidizing substance layer 81′_2 may be etched using the etching solution to form the pixel electrode 82′ that includes the doped zinc oxide layer pattern 82_1 and the anti-oxidizing substance layer pattern 82′_2 shown in FIG. 10.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

As described above, a thin film transistor substrate according to embodiments of the present invention and a method of producing the same have the following one or more advantages.

First, since a pixel electrode that is formed of a doped zinc oxide layer and an anti-oxidizing substance is provided, the resistivity of the pixel electrode is reduced.

Second, since the pixel electrode that is formed of the doped zinc oxide layer and the anti-oxidizing substance is provided, the probe used during a performance test is prevented from being contaminated.

Third, since the pixel electrode that includes low-priced zinc oxide as its main component, the production cost of the thin film transistor substrate is reduced.

What is claimed is:

1. A thin film transistor substrate comprising:
a gate wiring line formed on an insulating substrate;
a data wiring line crossing the gate wiring line while being insulated from the gate wiring line; and
a pixel electrode connected to a portion of the data wiring line and including a zinc oxide layer pattern doped with a dopant and an anti-oxidizing substance layer pattern.

2. The thin film transistor substrate of claim 1, wherein the dopant is a nonmetallic element having an atomic value lower than the atomic value of an oxygen atom.

3. The thin film transistor substrate of claim 2, wherein the dopant is formed of one or more selected from the group consisting of F and Cl.

4. The thin film transistor substrate of claim 1, wherein the dopant is a metallic element having an atomic value higher than the atomic value of zinc.

5. The thin film transistor substrate of claim 4, wherein the dopant is formed of one or more selected from the group consisting of B, Al, Ga, In, Si, Ge, Sn, Sc, Ti, Co, Cu, Y, and Hf.

6. The thin film transistor substrate of claim 5, wherein the composition ratio of zinc oxide and the dopant is 100:1 to 100:10 in terms of weight percent.

7. The thin film transistor substrate of claim 5, wherein the doped zinc oxide layer pattern has a thickness of 20 to 100 nm.

8. The thin film transistor substrate of claim 1, wherein the anti-oxidizing substance layer pattern is made of a nitride substance.

9. The thin film transistor substrate of claim 8, wherein the anti-oxidizing substance layer pattern has a thickness of 1 to 10 nm.

10. A method of producing a thin film transistor substrate, the method comprising:
forming a gate wiring line on an insulating substrate;
forming a data wiring line crossing the gate wiring line while being insulated from the gate wiring line; and
forming a pixel electrode connected to a portion of the data wiring line and including a zinc oxide layer pattern doped with a dopant and an anti-oxidizing substance layer pattern.

11. The method of claim 10, wherein the forming of the pixel electrode comprises:
forming a doped zinc oxide layer using a sputtering process;
forming an anti-oxidizing substance layer using a nitrogen gas; and
etching the doped zinc oxide layer and the anti-oxidizing substance layer to form the doped zinc oxide layer pattern and the anti-oxidizing substance layer pattern.

12. The method of claim 11, wherein the sputtering process is performed using an argon gas.

13. The method of claim 12, wherein flow of the argon gas is 40 to 300 sccm.

14. The method of claim 11, wherein the sputtering process is performed in a chamber at a pressure of 0.1 to 2.0 Pa.

15. The method of claim 11, wherein the anti-oxidizing substance layer is formed by the sputtering process using a gas mixture of a nitrogen gas and an argon gas.

16. The method of claim 15, wherein a flow ratio of the nitrogen gas and the argon gas used to form the anti-oxidizing substance layer is 1:4 to 4:1.

17. The method of claim 11, wherein the anti-oxidizing substance layer is formed using heat treatment of the doped zinc oxide layer in a nitrogen gas atmosphere.

18. The method of claim 17, wherein a temperature of the heat treatment is 100 to 300° C.

19. The method of claim 10, wherein the dopant is a nonmetallic element having an atomic value lower than the atomic value of an oxygen atom.

20. The method of claim 19, wherein the dopant is formed of one or more selected from the group consisting of F and Cl.

21. The method of claim 10, wherein the dopant is a metallic element having an atomic value higher than the atomic value of zinc.

22. The method of claim 21, wherein the dopant is formed of one or more selected from the group consisting of B, Al, Ga, In, Si, Ge, Sn, Sc, Ti, Co, Cu, Y, and Hf.

23. The method of claim 10, wherein the anti-oxidizing substance layer pattern is made of a nitride substance.
